(19) United States
(12) Patent Application Publication
(10) Pub. No.: US 2010/0132778 A1
(43) Pub. Date: Jun. 3, 2010

(54) SOLAR CELL, METHOD OF FABRICATING THE SAME AND APPARATUS FOR FABRICATING THE SAME

(75) Inventors: Jin Hong, Gyeonggi-do (KR); Chang-Sil Yang, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD., Gyeonggi-do (KR)

(21) Appl. No.: 12/597,495

(22) PCT Filed: Jun. 20, 2008
(86) PCT No.: PCT/KR08/03531

§ 371 Date: Oct. 25, 2009

(30) Foreign Application Priority Data
Jun. 21, 2007 (KR) 10-2007-0061016

(51) Int. Cl. H01L 31/00; H01L 31/18

(52) U.S. Cl. 136/255; 438/96; 118/715; 257/E31.047; 257/E31.043

(57) ABSTRACT

A method of fabricating a solar cell includes forming a first electrode on a transparent substrate; forming a first impurity-doped semiconductor layer on the first electrode; forming a light absorption layer on the first impurity-doped semiconductor layer and including a plurality of sub-layers, the plurality of sub-layers having stepwisely varying energy band gaps; forming a second impurity-doped semiconductor layer on the light absorption layer; and forming a second electrode on the second impurity-doped semiconductor layer.

### TECHNICAL FIELD

The present invention relates to a solar cell, and more particularly, to a high efficiency solar cell including a light absorption layer of at least two sub-layers, which have stepwisely varying energy band levels, a method of fabricating the solar cell and an apparatus for fabricating the solar cell.

### BACKGROUND ART

As concerns about clean energy such as solar power for coping with exhaust of fossil resources and environmental pollution increase, a solar cell generating an electromotive force using sunlight has been the subject of recent research.

Solar cells generate an electromotive force from diffusion of minority carriers, which are excited by sunlight, in P-N (positive-negative) junction layer. Single crystalline silicon, polycrystalline silicon, amorphous silicon or compound semiconductor may be used for the solar cells.

Although solar cells using single crystalline silicon or polycrystalline silicon have a relatively high energy-converting efficiency, solar cells using single crystalline silicon or polycrystalline silicon have a relatively high material cost and a relatively complicated fabrication process. Accordingly, a solar cell using amorphous silicon or compound semiconductor on a cheap substrate such as glass or plastic has been widely researched and developed. Specifically, a solar cell has advantages in a large-sized substrate and a flexible substrate so that a flexible large-sized solar cell can be produced.

FIG. 1 is a cross-sectional view of an amorphous silicon solar cell according to the related art. In FIG. 1, a first electrode 12, a semiconductor layer 13 and a second electrode 14 are sequentially formed on a substrate 11. The transparent substrate 11 includes glass or plastic. The first electrode 12 includes a transparent conductive oxide (TCO) material for transmission of incident light from the transparent substrate 11. The semiconductor layer 13 includes amorphous silicon (a-Si:H). In addition, the semiconductor layer 13 includes a p-type semiconductor layer 13a, an intrinsic semiconductor layer 13b and an n-type semiconductor layer 13c sequentially on the front electrode 12, which form a PIN (positive-intrinsic-negative) junction layer. The intrinsic semiconductor layer 13b, which may be referred to as an active layer, functions as a light absorption layer increasing efficiency of the solar cell. The second electrode 14 is formed by depositing a TCO material or a metallic material such as aluminum (Al), copper (Cu) and silver (Ag).

When sunlight is irradiated onto the transparent substrate 11 of the solar cell having the above-mentioned structure, minority carriers diffusing across the PIN junction layer of the semiconductor layer 13 on the transparent substrate 11 generate a voltage difference between the first electrode 12 and the second electrode 14, thereby generating an electromotive force.

The amorphous silicon solar cell has a relatively low energy-converting efficiency as compared with a single crystalline silicon solar cell or a polycrystalline silicon solar cell. In addition, as the amorphous silicon solar cell is exposed to light for a longer time period, the efficiency is further reduced according to a property-deterioration phenomenon, which is referred to as Staebler-Wronski effect.

To solve the above problems, a solar cell using microcrystalline silicon (nc-Si:H) instead of amorphous silicon has been suggested. The microcrystalline silicon as an intermediate material between amorphous silicon and single crystalline silicon has a grain size of several tens nano meters (nm) to several hundreds nm. In addition, the microcrystalline silicon does not have a property-deterioration phenomenon of amorphous silicon.

The intrinsic semiconductor layer of microcrystalline silicon has a thickness above about 2000 nm because of lower absorption coefficient of light, while the intrinsic semiconductor layer of amorphous silicon has a thickness of about 400 nm. In addition, since a deposition rate of microcrystalline silicon is lower than a deposition rate of amorphous silicon layer, thicker microcrystalline silicon is much lower productivity than thinner amorphous silicon.

Furthermore, a band gap of amorphous silicon is about 1.7 eV, while a band gap of microcrystalline silicon is about 1.1 eV, which is the same as a band gap of single crystalline silicon. Accordingly, amorphous silicon and microcrystalline silicon have difference in light absorption property. As a result, amorphous silicon absorbs light having a wavelength of about 350 nm to about 800 nm, while microcrystalline silicon absorbs light having a wavelength of about 350 nm to about 1200 nm.

Recently, a solar cell of a tandem (double) structure or a triple structure where PIN junction layers of amorphous silicon and microcrystalline silicon are sequentially formed has been widely used on the basis of the difference in light absorption property between amorphous silicon and microcrystalline silicon. For example, when a first PIN junction layer of amorphous silicon that absorbs light in a shorter wavelength band is formed on a transparent substrate onto which sunlight is irradiated and a second PIN junction layer of microcrystalline silicon that absorbs light in a longer wavelength band is formed on the first PIN junction layer of amorphous silicon, light absorption of the first and second PIN junction layers is improved, thereby improving energy-converting efficiency.

### DISCLOSURE OF INVENTION

### Technical Problem

Although the solar cell of a tandem structure or a triple structure has advantages in energy-converting efficiency as compared with a solar cell of a single structure of amorphous silicon or microcrystalline silicon, the solar cell of a tandem structure or a triple structure still has a problem of a relatively complicated fabrication process. Moreover, since the fabrication process for the solar cell of a tandem structure or a triple structure includes a deposition step of microcrystalline silicon, there exists a limitation in improvement of productivity.

### Technical Solution

Accordingly, the present invention is directed to a solar cell, a method of fabricating the solar cell and an apparatus for the solar cell that substantially obviate one or more of the problems due to limitations and disadvantages of the related art.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

An object of the present invention is to provide a high efficiency solar cell having a simplified fabrication process and an improved productivity, a method of fabricating the solar cell and an apparatus for the solar cell.

Another object of the present invention is to provide a high efficiency solar cell using microcrystalline silicon and amorphous silicon as a light absorption layer, a method of fabricating the solar cell and an apparatus for the solar cell.

To achieve these and other advantages and in accordance with the purpose of the invention, as embodied and broadly described, a method of fabricating a solar cell includes forming a first electrode on a transparent substrate; forming a first impurity-doped semiconductor layer on the first electrode; forming a light absorption layer on the first impurity-doped semiconductor layer and including a plurality of sub-layers, the plurality of sub-layers having stepwisely varying energy band gaps; forming a second impurity-doped semiconductor layer on the light absorption layer; and forming a second electrode on the second impurity-doped semiconductor layer.

In another aspect, a solar cell includes a transparent substrate; a first electrode on the transparent substrate; a first impurity-doped semiconductor layer on the first electrode; a light absorption layer on the first impurity-doped semiconductor layer and including a plurality of sub-layers, the plurality of sub-layers having stepwisely varying energy band gaps; a second impurity-doped semiconductor layer on the light absorption layer; and a second electrode on the second impurity-doped semiconductor layer.

In another aspect, an apparatus for fabricating a solar cell includes a transfer chamber including a transfer means for transferring a substrate; a load lock chamber coupled with a first side portion of the transfer chamber, the load lock chamber alternately having a vacuum state and an atmospheric pressure state for inputting and outputting the substrate; a first process chamber coupled with a second side portion of the transfer chamber, a first impurity-doped semiconductor layer formed on a first electrode on the substrate in the first process chamber; and a second process chamber coupled with a third side portion of the transfer chamber, a light absorption layer formed on the first impurity-doped semiconductor layer in the second process chamber, wherein a ratio of a silicon source material to a hydrogen gas is stepwisely varied such that the light absorption layer including a plurality of sub-layers having stepwisely varying energy band gaps.

In another aspect, an apparatus for fabricating a solar cell includes a transfer chamber including a transfer means for transferring a substrate; a load lock chamber coupled with a first side portion of the transfer chamber, the load lock chamber alternately having a vacuum state and an atmospheric pressure state for inputting and outputting the substrate; a first process chamber coupled with a second side portion of the transfer chamber, a first impurity-doped semiconductor layer formed on a first electrode on the substrate in the first process chamber; and a second process chamber coupled with a third side portion of the transfer chamber, a light absorption layer formed on the first impurity-doped semiconductor layer in the second process chamber, wherein a power to the second process chamber is stepwisely varied with a fixed ratio of a silicon source material to a hydrogen gas such that the light absorption layer including a plurality of sub-layers having stepwisely varying energy band gaps.

In another aspect, an apparatus for fabricating a solar includes a loading chamber alternately having a vacuum state and an atmospheric pressure state for inputting a substrate; a first process chamber coupled with a side portion of the loading chamber a first impurity-doped semiconductor layer formed on a first electrode on the substrate in the first process chamber; a second process chamber coupled with a side portion of the first process chamber, a light absorption layer formed on the first impurity-doped semiconductor layer in the second process chamber, wherein a ratio of a silicon source material to a hydrogen gas is stepwisely varied such that the light absorption layer including a plurality of sub-layers having stepwisely varying energy band gaps; and an unloading chamber coupled with a side portion of the second process chamber, the unloading chamber alternately having a vacuum state and an atmospheric pressure state for outputting the substrate.

In another aspect, an apparatus for fabricating a solar includes a loading chamber alternately having a vacuum state and an atmospheric pressure state for inputting a substrate; a first process chamber coupled with a side portion of the loading chamber a first impurity-doped semiconductor layer formed on a first electrode on the substrate in the first process chamber; a second process chamber coupled with a side portion of the first process chamber, a light absorption layer formed on the first impurity-doped semiconductor layer in the second process chamber, wherein a power to the second process chamber is stepwisely varied with a fixed ratio of a silicon source material to a hydrogen gas such that the light absorption layer including a plurality of sub-layers having stepwisely varying energy band gaps; and an unloading chamber coupled with a side portion of the second process chamber, the unloading chamber alternately having a vacuum state and an atmospheric pressure state for outputting the substrate.

### Advantageous Effects

In a solar cell according to an embodiment of the present invention, since an intrinsic semiconductor layer as a light absorption layer has a plurality of sub-layers having difference in an energy band gap, light absorption band is broaden and energy-converting efficiency is improved. In addition, since a separate step of forming a microcrystalline silicon layer that has a relatively low deposition rate is omitted, a fabrication process for a solar cell according to an embodiment of the present invention is simplified as compared with a fabrication process for a tandem structure solar cell or a triple structure solar cell. As a result, productivity is improved.

### BRIEF DESCRIPTION OF THE DRAWINGS

The accompanying drawings, which are included to provide a further understanding of the invention and are incorporated in and constitute a part of this specification, illustrate embodiments of the invention.

FIG. 1 is a cross-sectional view of an amorphous silicon solar cell according to the related art

FIG. 2 is a flow chart showing a fabrication process of a solar cell according to an embodiment of the present invention;

FIGS. 3 to 6 are cross-sectional views showing a fabrication process of a solar cell according to an embodiment of the present invention;

FIG. 7 is a plan views showing a cluster type apparatus for a solar cell according to an embodiment of the present invention; and

FIG. 8 is a plan views showing an in-line type apparatus for a solar cell according to an embodiment of the present invention.

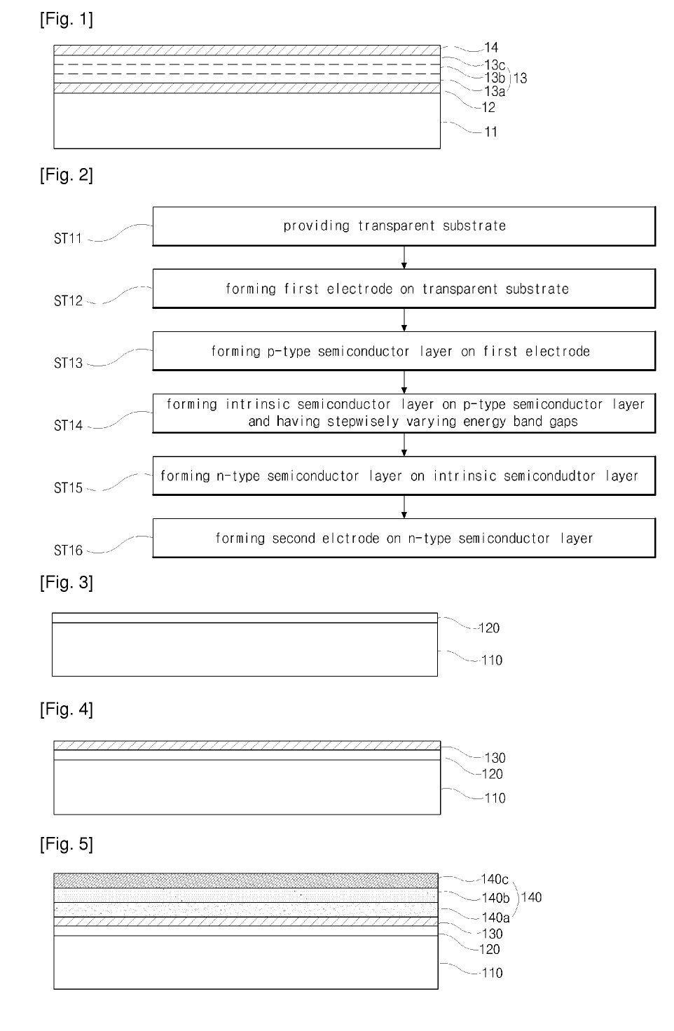

### MODE FOR THE INVENTION

FIG. 2 is a flow chart showing a fabrication process of a solar cell according to an embodiment of the present invention, and FIGS. 3 to 6 are cross-sectional views showing a fabrication process of a solar cell according to an embodiment of the present invention.

At steps of ST11 and ST12 and in FIG. 3, a transparent substrate 110 is provided, and a first electrode 120 on the transparent substrate 110. The transparent substrate 110 may include glass or transparent plastic. The first electrode 120 includes a transparent conductive oxide (TCO) material, for example, zinc oxide (ZnO), tin oxide (SnO₂) or indium-tin-oxide (ITO), for transmission of incident light through the transparent substrate 110. For example, the first electrode 120 may be formed by a metal-organic chemical vapor deposition (MOCVD) or a sputtering method.

As step of ST13 and in FIG. 4, a p-type semiconductor layer 130 is formed on the first electrode 120. The p-type semiconductor layer 130 may include amorphous silicon using silane (SiH₄) and hydrogen gas (H₂) or amorphous silicon carbide (SiC) using SiH₄ and a methan group material (CxHy, where x and y are positive integer). For example, the p-type semiconductor layer 130 may have a thickness of about 50 angstroms to about 500 angstroms. The p-type semiconductor layer 130 of amorphous silicon or amorphous SiC may be formed by an in-situ method where a source material and a p-type dopant, for example, diborane (B₂H₆) are provided into a single chamber.

As a step 14 and in FIG. 5, an intrinsic semiconductor layer 140 having a first sub-layer 140a, a second sub-layer 140b and a third sub-layer 140c is formed on the p-type semiconductor layer 130. The first sub-layer 140a faces the p-type semiconductor layer 130, and the second sub-layer 140b is disposed between the first and third sub-layers 140a and 140c. The intrinsic semiconductor layer 140 functions as a light absorption layer, and the first, second and third sub-layers 140a, 140b and 140c have different band gap levels from each other. Specially, the first, second and third sub-layers 140a, 140b and 140c have step wisely varying band gap levels.

The first sub-layer 140a is formed of amorphous silicon and has an energy band gap of about 1.7 eV. The third sub-layer 140c is formed of microcrystalline silicon and has an energy band gap of about 1.1 eV. The second sub-layer 140b has an energy band gap between the first sub-layer 140a of amorphous silicon and the second sub-layer 140c of microcrystalline silicon. Accordingly, the first, second and third sub-layers 140a, 140b and 140c have difference in light absorption property.

Accordingly, when light is incident onto the transparent substrate 110, the first sub-layer 140a of the intrinsic semiconductor layer 140 absorbs light in a relatively short wavelength band and the second sub-layer 140b of the intrinsic semiconductor layer 140 absorbs light having a relatively short wavelength band in light passing the first sub-layer 140a of the intrinsic semiconductor layer 140. The third sub-layer 140c of the intrinsic semiconductor layer 140 absorbs light having a longer wavelength band in light passing the second sub-layer 140b of the intrinsic semiconductor layer 140.

Although the solar cell according to an embodiment of the present invention does not include PIN junction layers of amorphous silicon and PIN junction layers of microcrystalline silicon of a tandem structure or a triple structure as an absorption layer, the light absorption band of the solar cell is broadened to cover a range from a shorter wavelength band to a longer wavelength band because the intrinsic semiconductor layer has the first, second and third sub-layers having different energy band gap levels, e.g., from amorphous silicon to microcrystalline silicon.

A ratio of H2 to a silicon source material, for example, SiH₄ or disilane (Si₂H₆) is stepwisely controlled to from the intrinsic semiconductor layer 140 having the above-mentioned multiple-layered structure.

When the intrinsic semiconductor layer 140 is formed in a capacitively coupled plasma enhanced chemical vapor deposition (PECVD) apparatus using a substrate supporter and a flat electrode, which is parallel to the substrate supporter, the experiment shows a phase transition from amorphous silicon to microcrystalline silicon with a ratio of H₂ to SiH₄ being above about 25 percentages. In other words, by controlling a concentration of a silicon source material, such as SiH₄, a phase transition from amorphous silicon to microcrystalline silicon is induced. When a volumetric ratio of crystals is about 50 percentages, the phase transition from amorphous silicon to microcrystalline silicon may begin. Accordingly, for example, the first sub-layer 140a is formed using the capacitively coupled PECVD with a ratio of H₂ to SiH₄ being much smaller than about 25 percentages. Moreover, the second sub-layer 140b is formed with a ratio H₂ to SiH₄being about 25 percentages, and the third sub-layer 140c is formed with a ratio of H₂ to SiH₄being much greater than 25 percentages. As a result, the first sub-layer 140a is formed of amorphous silicon, the third sub-layer 140c is formed of microcrystalline amorphous silicon, and the second sub-layer 140b is formed of silicon having an energy band gap between that of amorphous silicon and that of microcrystalline amorphous silicon.

On the other hand, when the intrinsic semiconductor layer 140 is formed by an high density plasma (HDP) deposition apparatus using an inductive coupled plasma source, a phase transition from amorphous silicon to microcrystalline silicon with a ratio of H₂ to SiH₄ being above about 10 percentages. Accordingly, for example, the first sub-layer 140a of amorphous silicon is formed using the HDP deposition apparatus with a ratio of H₂ to SiH₄ being much smaller than about 10 percentages. Moreover, the second sub-layer 140b is formed with a ratio H₂ to SiH₄being about 10 percentages, and the third sub-layer 140c of microcrystalline silicon is formed with a ratio of H₂ to SiH₄ being much greater than 10 percentages. Accordingly, for example, a ratio of H₂ to SiH₄ is stepwisely controlled from a first ratio smaller than about 10 percentages to a second ratio being about 10 percentages and from the second ratio to a third ratio greater than about 10 percentages.

Each of the first, second and third sub-layers 140a, 140b and 140c may have a thickness of about 500 angstroms to 20000 angstroms.

The above triple-layered structure is not essential for the intrinsic semiconductor layer 140. For example, the intrinsic semiconductor layer may have two sub-layers of an amorphous silicon layer and a microcrystalline silicon layer. The intrinsic semiconductor layer may have at least four sub-layers. A volumetric ratio of H₂ to SiH₄ or Si₂H₆ is controlled with a range of about 2 percentages to about 80 percentages to obtain the intrinsic semiconductor layer of the above multiple-layered structure. The sub-layers of the intrinsic semiconductor layer have difference in an energy band gap. Moreover, a sub-layer, which is closer to the p-type semiconductor layer, of the intrinsic semiconductor layer has a larger energy band gap.

On the other hand, a phase transition from amorphous silicon to microcrystalline silicon is induced by changing a power supplied to a deposition apparatus with a fixed ratio of a silicon source material, for example, SiH₄ or Si₂H₆, to H₂. The supplied power for a phase transition from amorphous silicon to microcrystalline silicon is determined on the bais of volume or pressure of a chamber of the deposition apparatus or density or partial pressure of the silicon source material. For example, when a substrate having a size of 730 mm*920 mm is processed in a PECVD apparatus and a high frequency power of about 1 kW is supplied to a plasma source, a phase transition from amorphous silicon to microcrystalline silicon is induced. The power is stepwisely controlled.

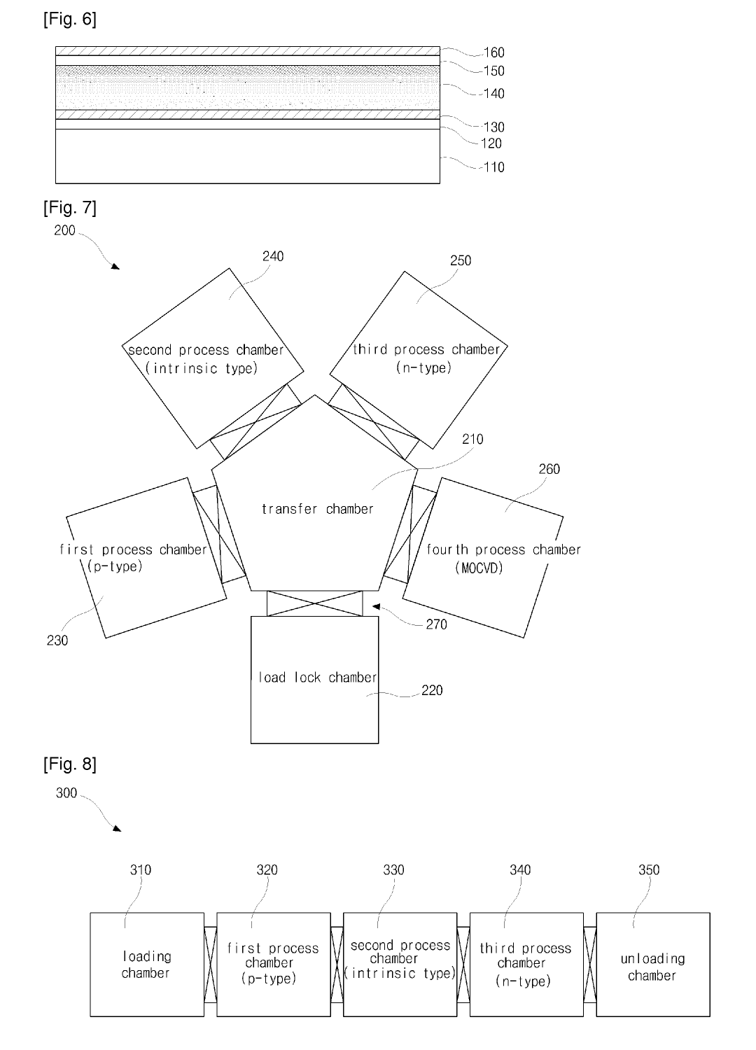

As steps 15 and 16 and in FIG. 6, an n-type semiconductor layer 150 and a second electrode 160 are sequentially formed on the intrinsic semiconductor layer 140. The n-type semiconductor layer 150 may be formed in a different chamber than the intrinsic semiconductor layer 140. However, the n-type semiconductor layer 150 may be formed in the same chamber as the intrinsic semiconductor layer 140 for productivity. Since the third sub-layer 140c of the intrinsic semiconductor layer 140 is formed of microcrystalline silicon, the n-type semiconductor layer 150 is formed of microcrystalline silicon in the same chamber where the intrinsic semiconductor layer 140 is formed. The n-type semiconductor layer 150 may have the same energy band gap as the third sub-layer 140c of the intrinsic semiconductor layer 140. Phosphine (PH₃) as a dopant is used for the n-type semiconductor layer 150.

The second electrode 160 is formed on the n-type semiconductor layer 150. The second electrode 160 may be formed of a transparent conductive oxide (TCO) material, for example, ZnO or SnO₂, by a metal-organic chemical vapor deposition (MOCVD) or a sputtering method. The second electrode 160 may be a thin film of aluminum (Al), copper (Cu) or silver (Ag).

When sunlight is incident through the transparent substrate 110 of the solar cell according to the present invention, the first sub-layer 140a, which is closest to an interface between the p-type semiconductor layer 130 and the intrinsic semiconductor layer 140, absorbs light in a relatively short wavelength band because the first sub-layer 140a is formed of amorphous silicon. The light passing through the first sub-layer 140a and having a relatively long wavelength band is absorbed by the second sub-layer 140b or the third sub-layer 140c. Among the first, second and third sub-layers 140a, 140b and 140c, the third sub-layer 140c, which is closest to an interface between the n-type semiconductor layer 150 and the intrinsic semiconductor layer 140, has a smallest energy band gap. Accordingly, the solar cell according to the present invention has advantages in energy-converting efficiency with the same principle as the solar cell of a related art tandem structure or a related art triple structure.

An apparatus for fabricating the above solar cell is explained with reference to FIGS. 7 and 8.

FIG. 7 is a plan views showing a cluster type apparatus for a solar cell according to an embodiment of the present invention. In FIG. 7, a cluster type apparatus 200 for a solar cell includes a transfer chamber 210, a load lock chamber 220 and a plurality of process chambers, e.g., first to fourth process chambers 230 to 260. The load lock chamber 220 and the first to fourth process chambers 230 to 260 surround and are coupled with the transfer chamber 210. The transfer chamber 210 may include a transfer means such as a robot (not shown) therein to transfer a substrate between chambers. The transfer chamber 210 maintains a vacuum state during the fabrication process of the solar cell. The load lock chamber 220 is used as a buffer space for transferring a substrate between the transfer chamber 210 under a vacuum state and an exterior under an atmospheric pressure state. Accordingly, the load lock chamber 220 alternately has a vacuum state and an atmospheric pressure state.

For example, the first to fourth process chambers 230 to 260 are coupled with side portions of the transfer chamber 210. The p-type semiconductor layer 130 (of FIG. 4) is formed on the first electrode 120 (of FIG. 3), which is formed on the transparent substrate 110 (of FIG. 3), in the first process chamber 230, and the intrinsic semiconductor layer 140 (of FIG. 5) having a plurality of sub-layers, which have different energy band gaps, is formed on the p-type semiconductor layer 130 in the second process chamber 240. The n-type semiconductor layer 150 (of FIG. 6) is formed on the intrinsic semiconductor layer 140 in the third process chamber 250. In addition, the first electrode 120 and the second electrode 160 (of FIG. 6) are formed by a MOCVD method in the fourth process chamber 260. A slot valve 270 selectively opening and closing a substrate path is disposed between the transfer chamber 210 and each of the load lock chamber 220 and between the transfer chamber 210 and each of the first to fourth process chambers 230 to 260.

After the transparent substrate 110 is inputted into the load lock chamber 220, the load lock chamber 220 is evacuated to have a vacuum state of predetermined pressure. Next, the slot valve 270 between the load lock chamber 220 and the transfer chamber 210 is opened. The transparent substrate 110 is transferred from the load lock chamber 220 to the fourth process chamber 260 through the transfer chamber 210 by the transfer robot (not shown) to form the first electrode 120 on the transparent substrate 110. Next, in the first process chamber 230, the p-type semiconductor layer 130 is formed on the first electrode 120. The intrinsic semiconductor layer 140 is formed on the p-type semiconductor layer 130 after the transparent substrate 110 is transferred to the second process chamber 240. Similarly, the n-type semiconductor layer 150 is formed on the intrinsic semiconductor layer 140 after the transparent substrate 110 is transferred to the third process chamber 250. In the second process chamber 240, by controlling a ratio of a silicon source material to a hydrogen gas, the intrinsic semiconductor layer having a plurality of sub-layers, which have difference in an energy band gap, is formed.

The third sub-layer 140c (of FIG. 5) as an uppermost layer of the intrinsic semiconductor layer 140 is formed of microcrystalline silicon. Accordingly, when the n-type semiconductor layer 150 is formed of microcrystalline silicon, the third sub-layer 140c contacting the n-type semiconductor layer 150 and the n-type semiconductor layer 150 may be sequentially formed in the second process chamber 240. In this case, the third process chamber 250 may be omitted.

After the n-type semiconductor layer 150 is formed on the intrinsic semiconductor layer 140 in the second process chamber 240 or the third process chamber 250, the transparent substrate 110 is transferred to the fourth process chamber 260 to form the second electrode 160 on the n-type semiconductor layer 150. Next, the transparent substrate 110 is outputted from the apparatus 200 through the load lock chamber 220.

FIG. 8 is a plan views showing an in-line type apparatus for a solar cell according to an embodiment of the present invention. In FIG. 8, an in-line type apparatus 300 for a solar cell includes a loading chamber 310, first to third process chambers 320 to 340 and an unloading chamber 350. The loading chamber 310, the first to third process chambers 320 to 340 and the unloading chamber 350 are serially coupled with each other. A substrate is inputted into the loading chamber 310 and outputted from the unloading chamber 350. Each of the loading chamber 310, the first to third process chambers 320 to 340 and the unloading chamber 350 includes an in-line type transferring means such as a roller or a linear motor to transfer a substrate.

The first to third process chambers 320 to 340 maintains a vacuum state during the fabrication process of the solar cell. Since a substrate is transferred between an exterior under an atmospheric pressure state and each of the first and third process chambers 320 and 340 under a vacuum state, each of the loading chamber 310 and the unloading chamber 350 alternately has a vacuum state and an atmospheric pressure state.

After the transparent substrate 110 (of FIG. 3) having the first electrode 120 (of FIG. 3) thereon is transferred to the first process chamber 320, the p-type semiconductor layer 130 (of FIG. 4) is formed on the first electrode 120. The intrinsic semiconductor layer 140 (of FIG. 5) having a plurality of sub-layers is formed on the p-type semiconductor layer 130 after the transparent substrate 110 is transferred to the second process chamber 330. Similarly, the n-type semiconductor layer 150 (of FIG. 6) is formed on the intrinsic semiconductor layer 140 after the transparent substrate 110 is transferred to the third process chamber 340. After the transparent substrate 110 having the first electrode 120, the p-type semiconductor layer 130, the intrinsic semiconductor layer 140 and the n-type semiconductor layer 150 thereon is outputted from the in-line type apparatus 300 for a thin film solar cell, the second electrode 160 (of FIG. 6) may be formed on the n-type semiconductor layer 150 in another apparatus such as a sputter or an MOCVD apparatus. The n-type semiconductor layer 150 is formed in the second process chamber 330 or the third process chamber 340. When the n-type semiconductor layer 150 is formed of the same material, for example, microcrystalline silicon, of the third sub-layer 140c as a top layer of the intrinsic semiconductor layer 140, the third sub-layer 140c and the n-type semiconductor layer 150 may be sequentially formed in the second process chamber 330. In this case, the third process chamber 340 may be omitted.

A first MOCVD process chamber for the first electrode 120 may be disposed between the loading chamber 310 and the first process chamber 320, and a second MOCVD chamber for the second electrode 160 may be disposed between the third process chamber 340 and the unloading chamber 340. One of the first and second MOCVD chambers may be omitted. The first and second electrodes 160 may be formed in the other one of the first and second MOCVD chambers.

It will be apparent to those skilled in the art that various modifications and variations can be made in a solar cell, a method of fabricating the solar cell and an apparatus for fabricating the solar cell of the present invention without departing from the spirit or scope of the invention. Thus, it is intended that the present invention cover the modifications and variations of this invention provided they come within the scope of the appended claims and their equivalents.

1. A method of fabricating a solar cell, comprising:
forming a first electrode on a transparent substrate;
forming a first impurity-doped semiconductor layer on the first electrode;
forming a light absorption layer on the first impurity-doped semiconductor layer and including a plurality of sub-layers, the plurality of sub-layers having stepwisely varying energy band gaps;
forming a second impurity-doped semiconductor layer on the light absorption layer; and
forming a second electrode on the second impurity-doped semiconductor layer.

2. The method according to claim 1, wherein a first sub-layer of the plurality of sub-layers closer to the first impurity-doped semiconductor layer has a bigger energy band gap and a second sub-layer of the plurality of sub-layers closer to the second impurity-doped semiconductor layer has a smaller energy band gap.

3. The method according to claim 1, wherein each of the plurality of sub-layers has a thickness of about 500 angstroms to about 20000 angstroms.

4. The method according to claim 1, wherein a first sub-layer of the plurality of sub-layers closer to the first impurity-doped semiconductor layer has a bigger energy band gap and a second sub-layer of the plurality of sub-layers closer to the second impurity-doped semiconductor layer has a smaller energy band gap.

5. The method according to claim 4, wherein the step of forming the light absorption layer comprises:
forming the first sub-layer on the first impurity-doped semiconductor layer by supplying a hydrogen gas and a silicon source material with a first ratio of the hydrogen gas to the silicon source material; and
forming the second sub-layer on the first sub-layer by supplying the hydrogen gas and the silicon source material with a second ratio of the hydrogen gas to the silicon source material, the second ratio being greater than the first ratio.

6. The method according to claim 5, wherein the silicon source material includes one of silane (SiH₄) and disilane (Si₂H₆).

7. The method according to claim 5, wherein the first sub-layer includes amorphous silicon and the second sub-layer includes microcrystalline silicon.

8. The method according to claim 5, wherein each of the first and second ratios has a range of about 20 percentages to about 80 percentages.

9. The method according to claim 5, wherein the step of forming the light absorption layer further comprises:
forming a third sub-layer between the first and second sub-layers by supplying the hydrogen gas and the silicon source material with a third ratio of the hydrogen gas to the silicon source material, the third ratio being greater than the first ratio and smaller than the second ratio.

10. The method according to claim 9, wherein the third ratio is about 25 percentages.

11. The method according to claim 4, wherein the step of forming the light absorption layer comprise;
forming the first sub-layer on the first impurity-doped semiconductor layer by supplying a first power to a chamber with a fixed ratio of a silicon source material to a hydrogen gas; and
forming the second sub-layer on the first sub-layer by supplying a second power to the chamber with the fixed ratio of the silicon source material to the hydrogen gas, the second power being greater than the first power.

12. The method according to claim 11, wherein the step of forming the light absorption layer further comprises:
forming a third sub-layer between the first and second sub-layers by supplying a third power to the chamber with the fixed ratio of the silicon source material to the hydrogen gas, the third power being greater than the first power and smaller than the second power.

13. The method according to claim 1, wherein the steps of the forming the light absorption layer and the second impurity-doped semiconductor layer are sequentially process in a single chamber.

14. The method according to claim 13, wherein both a sub-layer contacting the second impurity-doped semiconductor layer and the second impurity-doped semiconductor layer include microcrystalline silicon.

15. A solar cell, comprising:
a transparent substrate;
a first electrode on the transparent substrate;
a first impurity-doped semiconductor layer on the first electrode;
a light absorption layer on the first impurity-doped semiconductor layer and including a plurality of sub-layers, the plurality of sub-layers having stepwisely varying energy band gaps;
a second impurity-doped semiconductor layer on the light absorption layer; and
a second electrode on the second impurity-doped semiconductor layer.

16. The solar cell according to claim 15, wherein a first sub-layer of the plurality of sub-layers closer to the first impurity-doped semiconductor layer has a bigger energy band gap and a second sub-layer of the plurality of sub-layers closer to the second impurity-doped semiconductor layer has a smaller energy band gap.

17. The solar cell according to claim 15, wherein a sub-layer of the plurality of sub-layers contacting the second impurity-doped semiconductor layer and the second impurity-doped semiconductor layer has the same energy band gap.

18. The solar cell according to claim 15, wherein the first impurity-doped semiconductor layer includes p-type amorphous silicon, the light absorption layer includes intrinsic amorphous silicon, and the second impurity-doped semiconductor layer includes n-type amorphous silicon.

19. The solar cell according to claim 12, wherein a first sub-layer contacting the first impurity-doped semiconductor layer includes amorphous silicon and a second sub-layer contacting the second impurity-doped semiconductor layer includes microcrystalline silicon.

20. An apparatus for fabricating a solar cell, comprising:
a transfer chamber including a transfer means for transferring a substrate;
a load lock chamber coupled with a first side portion of the transfer chamber, the load lock chamber alternately having a vacuum state and an atmospheric pressure state for inputting and outputting the substrate;
a first process chamber coupled with a second side portion of the transfer chamber, a first impurity-doped semiconductor layer formed on a first electrode on the substrate in the first process chamber; and
a second process chamber coupled with a third side portion of the transfer chamber, a light absorption layer formed on the first impurity-doped semiconductor layer in the second process chamber, wherein a ratio of a hydrogen gas to a silicon source material is stepwisely varied such that the light absorption layer including a plurality of sub-layers having stepwisely varying energy band gaps.

21. The apparatus according to claim 20, further comprising a third process chamber coupled with a fourth side portion of the transfer chamber, a second impurity-doped semiconductor layer formed on the light absorption layer in the third process chamber.

22. The apparatus according to claim 20, wherein a second impurity-doped semiconductor layer is formed on the light absorption layer in the second process chamber.

23. The apparatus according to claim 22, wherein the second impurity-doped semiconductor layer is formed of a material having the same band gap energy band as a top sub-layer of the light absorption layer contacting the second impurity-doped semiconductor layer.

24. The apparatus according to claim 22, further comprising a third process chamber coupled with a fifth side portion of the transfer chamber, the first electrode and a second electrode formed on the transparent substrate and the second impurity-doped semiconductor layer, respectively, in the third process chamber.

25. The apparatus according to claim 20, wherein a sub-layer of the plurality of sub-layers closer to the first impurity-doped semiconductor layer has a bigger energy band gap.

26. An apparatus for fabricating a solar cell, comprising:
a transfer chamber including a transfer means for transferring a substrate;
a load lock chamber coupled with a first side portion of the transfer chamber, the load lock chamber alternately having a vacuum state and an atmospheric pressure state for inputting and outputting the substrate;
a first process chamber coupled with a second side portion of the transfer chamber, a first impurity-doped semiconductor layer formed on a first electrode on the substrate in the first process chamber; and
a second process chamber coupled with a third side portion of the transfer chamber, a light absorption layer formed on the first impurity-doped semiconductor layer in the second process chamber, wherein a power to the second process chamber is stepwisely varied with a fixed ratio of a hydrogen gas to a silicon source material such that the light absorption layer including a plurality of sub-layers having stepwisely varying energy band gaps.

27. An apparatus for fabricating a solar, comprising:
a loading chamber alternately having a vacuum state and an atmospheric pressure state for inputting a substrate;
a first process chamber coupled with a side portion of the loading chamber a first impurity-doped semiconductor layer formed on a first electrode on the substrate in the first process chamber;
a second process chamber coupled with a side portion of the first process chamber, a light absorption layer formed on the first impurity-doped semiconductor layer in the second process chamber, wherein a ratio of a hydrogen gas to a silicon source material is stepwisely varied such that the light absorption layer including a plurality of sub-layers having stepwisely varying energy band gaps; and
an unloading chamber coupled with a side portion of the second process chamber, the unloading chamber alternately having a vacuum state and an atmospheric pressure state for outputting the substrate.

28. The apparatus according to claim 27, further comprising a third process chamber, a second impurity-doped semiconductor layer formed on the light absorption layer in the third process chamber.

29. The apparatus according to claim 28, further comprising a fourth process chamber between the loading chamber and the first process chamber or between the third process chamber and the unloading process chamber, wherein the first electrode and a second electrode are formed on the transparent substrate and the second impurity-doped semiconductor layer, respectively, in the fourth process chamber.

30. The apparatus according to claim 27, wherein a second impurity-doped semiconductor layer is formed on the light absorption layer in the second process chamber.

31. The apparatus according to claim 30, wherein the second impurity-doped semiconductor layer is formed of a material having the same band gap energy band as a top sub-layer of the light absorption layer contacting the second impurity-doped semiconductor layer.

32. The apparatus according to claim 30, further comprising a third process chamber between the loading chamber and the first process chamber or between the second process chamber and the unloading process chamber, wherein the first electrode and a second electrode are formed on the transparent substrate and the second impurity-doped semiconductor layer, respectively, in the fourth process chamber.

33. An apparatus for fabricating a solar, comprising:
a loading chamber alternately having a vacuum state and an atmospheric pressure state for inputting a substrate;
a first process chamber coupled with a side portion of the loading chamber a first impurity-doped semiconductor layer formed on a first electrode on the substrate in the first process chamber;
a second process chamber coupled with a side portion of the first process chamber, a light absorption layer formed on the first impurity-doped semiconductor layer in the second process chamber, wherein a power to the second process chamber is stepwisely varied with a fixed ratio of a silicon source material to a hydrogen gas such that the light absorption layer including a plurality of sub-layers having stepwisely varying energy band gaps; and
an unloading chamber coupled with a side portion of the second process chamber, the unloading chamber alternately having a vacuum state and an atmospheric pressure state for outputting the substrate.
